(19) United States
(12) Patent Application Publication
(10) Pub. No.: US 2023/0339796 A1
(43) Pub. Date: Oct. 26, 2023

(54) GLASS PACKAGES AND METHODS OF MANUFACTURE

(71) Applicant: CORNING INCORPORATED, CORNING, NY (US)

(72) Inventors: Rocco Lafleur, Wallisellen (CH); Ernesto Sanchez, Jr., Oxnard, CA (US)

(21) Appl. No.: 18/023,242

(22) PCT Filed: Aug. 27, 2021
(86) PCT No.: PCT/US2021/047904

§ 371 Date: Feb. 24, 2023

Related U.S. Application Data
(60) Provisional application No. 63/073,747, filed on Sep. 2, 2020.

(51) Int. Cl. C03B 29/02; C03C 17/06; C03C 17/22

(52) U.S. Cl. CPC C03B 29/025; C03C 17/06; C03C 17/22

(57) ABSTRACT

A glass package includes a glass body with a rim at least partially circumscribing a cavity and a glass lid with a peripheral portion bonded to the rim and a central portion overlying the cavity. A bond between the lid and the body includes interior and exterior perimeter bonds and a filler bond disposed at least partially between the interior and exterior perimeter bonds. The filler bond includes Sa plurality of first bond paths that are substantially parallel to each other and a plurality of second bond paths that are substantially parallel to each other. The plurality of first bond paths and the plurality of second bond paths intersect each other to form a grid pattern.

### CROSS-REFERENCE TO RELATED APPLICATIONS

This application claims the benefit of priority under 35 U.S.C. § 119 of U.S. Provisional Application Ser. No. 63/073,747 filed on Sep. 2, 2020, the content of which is relied upon and incorporated herein by reference in its entirety.

### BACKGROUND

### 1. Field

This disclosure relates to glass packages and methods of manufacturing the same.

### 2. Technical Background

Glass packages can be used for a variety of products including, for example, microfluidic devices, sensors, microelectronics, and microelectromechanical systems (MEMS) devices. In some devices, it can be beneficial for the glass package to have a hermetically sealed cavity in which a material (e.g., solid or fluid material), electronic, mechanical, or other component can be placed. The glass package can protect the component within the sealed cavity from air, moisture, or other potential contaminants that could damage or hinder operation of the component.

### SUMMARY

Disclosed herein are glass packages and methods of manufacturing glass packages.

Disclosed herein is a glass package comprising a glass body comprising a rim at least partially circumscribing a cavity within the glass body and a glass lid comprising a peripheral portion bonded to the rim of the glass body and a central portion overlying the cavity. A bond between the glass lid and the glass body comprises an interior perimeter bond, an exterior perimeter bond, and a filler bond. The interior perimeter bond is disposed adjacent to and extends in an interior bond path along an interior perimeter of the rim. The exterior perimeter bond is disposed adjacent to and extends in an exterior bond path along an outer perimeter of the rim. The filler bond is disposed at least partially between the interior perimeter bond and the exterior perimeter bond and comprises a plurality of first bond paths that are substantially parallel to each other and a plurality of second bond paths that are substantially parallel to each other. The plurality of first bond paths and the plurality of second bond paths intersect each other to form a grid pattern.

It is to be understood that both the foregoing general description and the following detailed description are merely exemplary, and are intended to provide an overview or framework to understanding the nature and character of the claimed subject matter. The accompanying drawings are included to provide a further understanding and are incorporated in and constitute a part of this specification. The drawings illustrate one or more embodiments, and together with the description, serve to explain principles and operation of the various embodiments.

### BRIEF DESCRIPTION OF THE DRAWINGS

FIG. 1 is a schematic top view of some embodiments of a glass package.

FIG. 2 is a schematic cross-sectional view of some embodiments of a glass package.

FIG. 3 is a photograph depicting a cross-section of some embodiments of a glass package.

FIG. 4 is a partial top view of some embodiments of a bond of a glass package.

FIG. 5 is a partial close-up view of some embodiments of a bond of a glass package.

FIG. 6 is a photograph depicting some embodiments of two adjacent glass packages disposed in a package wafer.

FIG. 7 is a partial top view of some embodiments of bonds of two adjacent glass packages disposed in a package wafer.

FIG. 8 is a partial top view of some embodiments of a glass package with air trapped in the bond.

### DETAILED DESCRIPTION

Reference will now be made in detail to exemplary embodiments which are illustrated in the accompanying drawings. Whenever possible, the same reference numerals will be used throughout the drawings to refer to the same or like parts. The components in the drawings are not necessarily to scale, emphasis instead being placed upon illustrating the principles of the exemplary embodiments.

Numerical values, including endpoints of ranges, can be expressed herein as approximations preceded by the term “about,” “approximately,” or the like. In such cases, other embodiments include the particular numerical values. Regardless of whether a numerical value is expressed as an approximation, two embodiments are included in this disclosure: one expressed as an approximation, and another not expressed as an approximation. It will be further understood that an endpoint of each range is significant both in relation to another endpoint, and independently of another endpoint.

In various embodiments, a glass package comprises a glass body comprising a rim at least partially circumscribing a cavity within the glass body and a glass lid comprising a peripheral portion bonded to the rim of the glass body and a central portion overlying the cavity. In some embodiments, a bond between the glass lid and the glass body comprises an interior perimeter bond, an exterior perimeter bond, and a filler bond. In some embodiments, the interior perimeter bond is disposed adjacent to and extends in an interior bond path along an interior perimeter of the rim. Additionally, or alternatively, the exterior perimeter bond is disposed adjacent to and extends in an exterior bond path along an outer perimeter of the rim. Additionally, or alternatively, the filler bond is disposed at least partially between the interior perimeter bond and the exterior perimeter bond and comprises a plurality of first bond paths that are substantially parallel to each other and a plurality of second bond paths that are substantially parallel to each other. In some embodiments, the plurality of first bond paths and the plurality of second bond paths intersect each other to form a grid pattern.

The bonds between the glass lid and the glass body described herein can improve the bond strength between the glass lid and the glass body, thereby enabling increased cavity size (e.g., length, width, and/or volume), operating temperature range, and/or hermeticity. For example, bonds comprising the filler bond disposed between the interior perimeter bond and the exterior perimeter bond as described herein can reduce the potential for the bond to fail (e.g., as a result of breakage of the glass lid proximate the bond) upon an increase in pressure within the cavity compared to bonds with the same interior perimeter bond and exterior perimeter bond, but without the filler bond. Such increased pressure within the cavity can be the result of heating a fluid (e.g., air) sealed within the cavity. Such an increased bond strength can enable increased cavity size, which may be accompanied by an increased pressure change over a given operating temperature, increased operating temperature range, and accompanying increased pressure change, and/or improved hermeticity (e.g., resulting from reduced breakage and accompanying leakage).

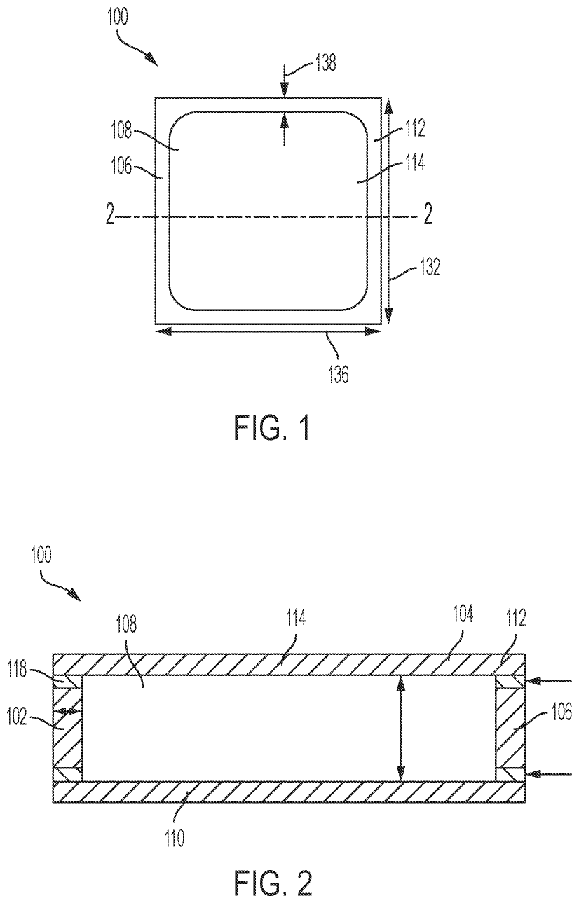

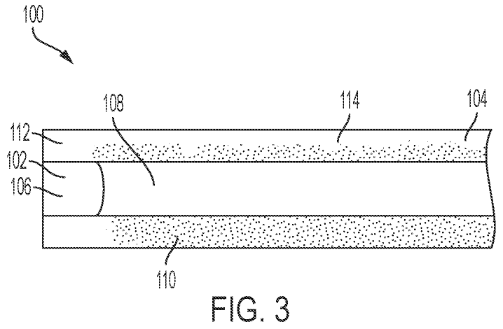

FIG. 1 is a schematic top view of some embodiments of a glass package 100, and FIGS. 2-3 are a schematic cross-sectional view and a photograph depicting a portion of a cross-section, respectively, of the glass package taken along line 2-2 of FIG. 1. In some embodiments, package 100 comprises a glass body 102 and a glass lid 104. Lid 104 can be bonded to body 102 to form package 100 as described herein. In some embodiments, body 102 comprises a rim 106 at least partially circumscribing a cavity 108 within the body. In some embodiments, the perimeter of cavity 108 has a substantially square shape (e.g., with rounded corners) as shown in FIG. 1. In other embodiments, the perimeter of cavity 108 comprises a circular, triangular, rectangular, or another polygonal or non-polygonal shape. A perimeter of package 100 can have the same or a different shape compared to the perimeter of cavity 108. For example, the perimeter of package 100 can have a square shape as shown in FIG. 1. In other embodiments, the perimeter of package 100 comprises a circular, triangular, rectangular, or another polygonal or non-polygonal shape. In some embodiments, a width of rim 106 comprises a distance (e.g., a minimum distance) between the perimeter of cavity 108 and the perimeter of package 100. For example, the width of rim 106 is at most about 1 mm. In some embodiments, the width of rim 106 is 1 mm, 0.9 mm, 0.8 mm, 0.7 mm, 0.6 mm, 0.5 mm, or any ranges defined by the listed values.

In some embodiments, body 102 comprises a base 110, and rim 106 extends from the base (e.g., around a periphery of the body) to define cavity 108. For example, rim 106 extends from base 110 and around a periphery (e.g., around a perimeter) of the base such that the rim circumscribes cavity 108. In such embodiments, rim 106 can define sidewalls of cavity 108 and/or base 110 can define a floor of the cavity. In some embodiments, base 110 and rim 106 can be discrete components bonded together to form body 102. For example, base 110 comprises a substantially planar sheet, rim 106 comprises a separate substantially planar sheet with an opening formed therein, and body 102 can be formed by bonding the base and the rim together. Base 110 and rim 106 can be bonded together as described herein with respect to bonding lid 104 to body 102 (e.g., using bond patterns described herein). In other embodiments, body 102 can be a monolithic structure, and base 110 and rim 106 can be integral portions of the monolithic structure. For example, body 110 can be formed by etching a sheet or block of material to form cavity 108 circumscribed by rim 106, leaving base 110 intact.

In some embodiments, lid 104 comprises a peripheral portion 112 bonded to rim 106 of body 102 and a central portion 114 overlying cavity 108. For example, lid 104 comprises a substantially planar sheet positioned on body 102 such that peripheral portion 112 is disposed adjacent rim 106 and central portion 114 is disposed adjacent cavity 108. In some embodiments, upon bonding lid 104 to body 102, the lid can define a ceiling of cavity 108.

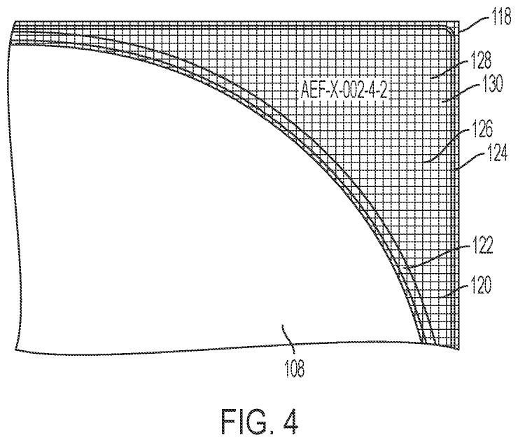

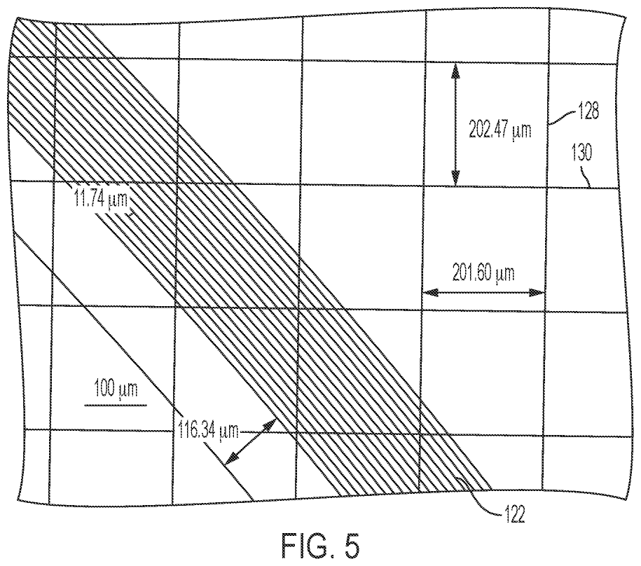

FIG. 4 is a partial top view of some embodiments of a bond 120 of package 100, viewed through lid 104. In some embodiments, bond 120 between lid 104 and body 102 comprises an interior perimeter bond 122, an exterior perimeter bond 124, and a filler bond 126. For example, interior perimeter bond 122 is disposed adjacent to and extends in an interior bond path along an interior perimeter of rim 106 and/or a perimeter of cavity 108. Additionally, or alternatively, exterior perimeter bond 124 is disposed adjacent to and extends in an exterior bond path along an outer perimeter of rim 106 and/or a perimeter of package 100. Additionally, or alternatively, filler bond 126 is disposed at least partially between interior perimeter bond 122 and exterior perimeter bond 124 (e.g., on an interior portion of rim 106). In some embodiments, filler bond 126 comprises a plurality of first bond paths 128 that are substantially parallel to each other and a plurality of second bond paths 130 that are substantially parallel to each other. For example, first bond paths 128 comprise bond lines extending in a first lateral direction (e.g., shown vertically in FIG. 4). Additionally, or alternatively, second bond paths 130 comprise bond lines extending in a second lateral direction (e.g., shown horizontally in FIG. 4). In some embodiments, first bond paths 128 and second bond paths 130 intersect each other to form a grid pattern. For example, the grid pattern comprises a plurality of rectangles (e.g., squares as shown in FIG. 4), parallelograms (e.g., diamonds or rhombuses), or another array of repeating polygonal shapes. Although first bond paths 128 and second bond paths 130 shown in FIG. 4 are linear, other embodiments are included in this disclosure. For example, the first bond paths and the second bond paths can have a curved, undulating, zig-zag, or other pattern in which spacing between adjacent bond paths is maintained to form a grid pattern as described herein. In some embodiments, the plurality of first bond paths 128 and the plurality of second bond paths 130 intersect each other at angles (e.g., the smallest angle formed at the intersection) of 45°, 50°, 55°, 60°, 65°, 70°, 75°, 80°, 85°, 90°, or any ranges defined by the listed values. For example, the plurality of first bond paths 128 and the plurality of second bond paths 130 intersect each other at angles of about 90°, whereby the grid pattern comprises a plurality of rectangles.

In some embodiments, filler bond 126 extends into an interstitial space between interior perimeter bond 122 and cavity 108. For example, interior perimeter bond 122 is disposed adjacent to, but spaced slightly away from the edge of cavity 108, and the grid pattern of filler bond 126 extends beyond the interior perimeter bond and up to the edge of the cavity. Such extension of filler bond 126 can further strengthen the bond between body 102 and lid 104. In some embodiments, interior perimeter bond 122 is spaced from the edge of cavity 108 by 5 μm, 10 μm, 20 μm, 30 μm, 40 μm, 50 μm, 60 μm, 70 μm, 80 μm, 90 μm, 100 μm, 110 μm, 120 μm, 130 μm, 140 μm, 150 μm, 160 μm, 170 μm, 180 μm, 190 μm, 200 μm, 210 μm, 220 μm, 230 μm, 240 μm, 250 μm, 260 μm, 270 μm, 280 μm, 290 μm, 300 μm, 310 μm, 320 μm, 330 μm, 340 μm, 350 μm, 360 μm, 370 μm, 380 μm, 390 μm, 400 μm, or any ranges defined by the listed values.

In some embodiments, bond 122 (e.g., interior perimeter bond 122, exterior perimeter bond 124, and/or filler bond 126) comprise laser bonds. For example, bond 122 can be formed by positioning lid 104 on body 102 and exposing the lid and/or the body to electromagnetic radiation using a bonding laser along the bond path. In some embodiments, package 100 comprises a bonding material 118 disposed between lid 104 and body 102 as shown in FIGS. 2 and 4. For example, bonding material 118 comprises a metal, a metal oxide, a glass (e.g., glass frit), a polymer, another bonding material, or a combination thereof. In some embodiments, bonding material 118 absorbs electromagnetic radiation at a wavelength of the bonding laser, whereby exposing the bonding material to the electromagnetic radiation along the bonding path heats the bonding material along the bonding path. In some embodiments, such heating of bonding material 118 causes the bonding material to diffuse into lid 104 and body 102, thereby bonding the lid and the body together. For example, such heating of bonding material 118 causes the bonding material to melt, vaporize, and/or form a plasma that diffuses into lid 104 and body 102. Additionally, or alternatively, such heating of bonding material 118 causes local softening and/or melting of the bonding material, lid 104, and/or body 102, thereby bonding the lid and the body together. In some embodiments, the laser bond comprises bonding material 118 diffused into each of body 102 and lid 104 and/or a mixture of material of one or more of the bonding material, the body, and/or the lid. In some embodiments, bonding material 118 can be omitted, and lid 104 and body 102 can be directly bonded together using the bonding laser. In some of such embodiments, the laser bond comprises a mixture of material of each of body 102 and lid 104. In various embodiments, any suitable laser bonding process can be used to form the laser bonds or bond paths described herein.

FIG. 5 is a partial close-up view of some embodiments of bond 122. In some embodiments, interior perimeter bond 122 and/or exterior perimeter bond 124 comprise a plurality of concentric bonds or a spiral bond that cooperatively form the respective perimeter bond. A pitch of such a plurality of concentric bonds or spiral bond can be expressed as a spacing between adjacent concentric bond paths or adjacent passes of the spiral. In some embodiments, the pitch of interior perimeter bond 122 and/or exterior perimeter bond 124 is, independently, 5 μm, 10 μm, 15 μm, 20 μm, 25 μm, 30 μm, 35 μm, 40 μm, 45 μm, 50 μm, or any ranges defined by the listed values. A pitch of the plurality of first bond paths 128 and the plurality of second bond paths 130 can be expressed as a spacing between adjacent bond paths. In various embodiments, the pitch of a concentric or spiral laser bond can depend on the spot size of the laser used to form the bond. For example, a ratio of the pitch to the spot size is 1:1 to 10:1. A smaller pitch can result in adjacent bond paths or passes overlapping each other, and a larger pitch can result in reduced bond strength. In some embodiments, a laser bond is formed using a laser with a 5 μm spot size, and the pitch of the resulting laser bonds is 5 μm to 50 μm.

In some embodiments, the pitch of the plurality of first bond paths 128 and/or the plurality of second bond paths 130 is, independently, 50 μm, 60 μm, 70 μm, 80 μm, 90 μm, 100 μm, 110 μm, 120 μm, 130 μm, 140 μm, 150 μm, 160 μm, 170 μm, 180 μm, 190 μm, 200 μm, 210 μm, 220 μm, 230 μm, 240 μm, 250 μm, 260 μm, 270 μm, 280 μm, 290 μm, 300 μm, 310 μm, 320 μm, 330 μm, 340 μm, 350 μm, 360 μm, 370 μm, 380 μm, 390 μm, 400 μm, or any ranges defined by the listed values. If the pitch of the plurality of first bond paths 128 and/or the plurality of second bond paths 130 is too large, filler bond 126 may not provide sufficient structural support, and if the pitch is too small, manufacturing may become difficult without an accompanying increase in structural support. In some embodiments, the pitch of the plurality of first bond paths 128 is substantially equal or equal to the pitch of the plurality of second bond paths 130. For example, a ratio of the pitch of the plurality of first bond paths 128 to the pitch of the plurality of second bond paths 130 is 0.5, 0.6, 0.7, 0.8, 0.9, 1, 1.1, 1.2, 1.3., 1.4, 1.5, or any ranges defined by the listed values. In some embodiments, a ratio of the pitch of the plurality of first bond paths 128 and/or the plurality of second bond paths to the pitch of interior perimeter bond 122 and/or exterior perimeter bond 124 is 5, 6, 7, 8, 9, 10, 11, 12, 13, 14, 15, 16, 17, 18, 19, 20, 21, 22, 23, 24, 25, 26, 27, 28, 29, 30, or any ranges defined by the listed values.

In some embodiments, bond 120 comprising interior perimeter bond 122, exterior perimeter bond 124, and filler bond 126 as described herein can enable cavity 108 to have an increased size compared to a bond with the interior perimeter bond and the exterior perimeter bond, but omitting the filler bond. For example, an area of central portion 114 of lid 104 is at least 2000 mm². In some embodiments, the area of central portion 114 of lid 104 is 2000 mm², 2100 mm², 2200 mm², 2300 mm², 2400 mm², 2500 mm², 2600 mm², 2700 mm², 2800 mm², 2900 mm², 3000 mm², 3100 mm², 3200 mm², 3300 mm², 3400 mm², 3500 mm², 3600 mm², 3700 mm², 3800 mm², 3900 mm², 4000 mm², or any ranges defined by the listed values. Additionally, or alternatively, each of a length and a width of cavity 108 is at least 50 mm. For example, the length and the width of cavity 108 are, independently, 50 mm, 60 mm, 70 mm, 80 mm, 90 mm, 100 mm, 200 mm, 300 mm, 400 mm, 500 mm, or any ranges defined by the listed values. Additionally, or alternatively, a depth of cavity 108 (e.g., a distance between interior surfaces of base 110 and lid 104) is at least 0.3 mm. For example, the depth of cavity 108 is 0.3 mm, 0.4 mm, 0.5 mm, 0.6 mm, 0.7 mm, 0.8 mm, 0.9 mm, 1 mm, or any ranges defined by the listed values. Additionally, or alternatively, a volume of cavity 108 is at least 1500 mm³. For example, the volume of cavity 108 is 1500 mm³, 1600 mm³, 1700 mm³, 1800 mm³, 1900 mm³, 2000 mm³, or any ranges defined by the listed values.

In some embodiments, bond 120 comprising interior perimeter bond 122, exterior perimeter bond 124, and filler bond 126 as described herein can enable package 100 to have a reduced thickness compared to a bond with the interior perimeter bond and the exterior perimeter bond, but omitting the filler bond (e.g., resulting from reduced stress at the interior perimeter bond and/or the exterior perimeter bond upon an increase in pressure within cavity 108). For example, lid 104 has a thickness of at most 0.5 mm. In some embodiments, the thickness of lid 104 is 0.5 mm, 0.4 mm, 0.3 mm, 0.2 mm, 0.1 mm, or any ranges defined by the listed values. Additionally, or alternatively, a thickness of glass package 100 is at most 1.5 mm. For example, the thickness of glass package 100 is 0.5 mm, 0.6 mm, 0.7 mm, 0.8 mm, 0.9 mm, 1 mm, 1.1 mm, 1.2 mm, 1.3 mm, 1.4 mm, 1.5 mm, or any ranges defined by the listed values.

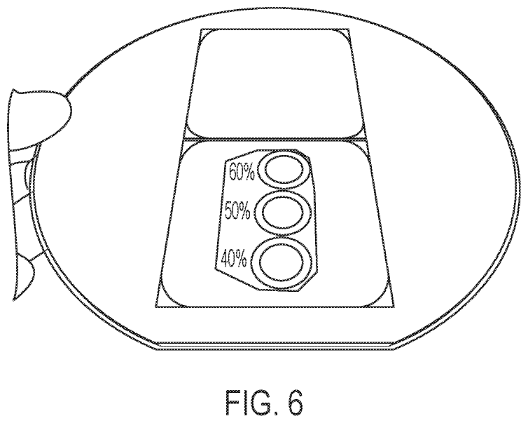

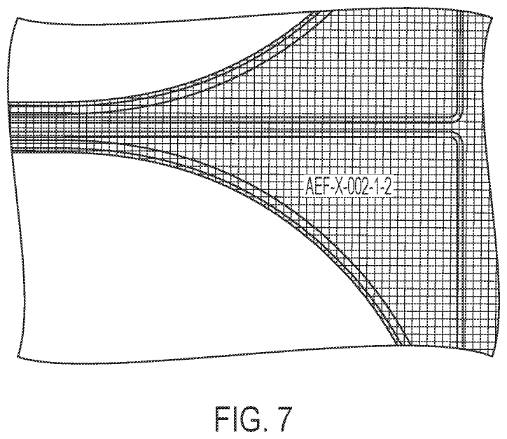

In some embodiments, multiple packages 100 can be disposed in a package wafer and/or manufactured using a wafer manufacturing process. FIG. 6 is a photograph depicting some embodiments of two adjacent glass packages disposed in a package wafer, and FIG. 7 is a partial top view of some embodiments of bonds 120 of the two adjacent packages 100 disposed in the package wafer. For example, the package wafer can be made by bonding a lid wafer to a body wafer comprising a plurality of cavities therein. In some embodiments, the perimeter of each package 100 can be defined by exterior perimeter bond 124 of the respective package. Spaces between adjacent exterior perimeter bonds 124 can serve as dicing lanes through which the package wafer can be diced (e.g., cut or severed) to separate adjacent packages 100 from each other (e.g., to singulate the packages). In some embodiments, filler bond 126 comprises a substantially continuous pattern extending between adjacent packages 100.

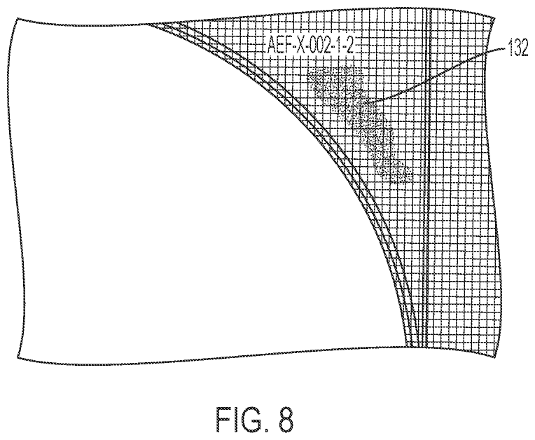

In some embodiments, a method of manufacturing package 100 comprises forming interior perimeter bond 122, forming filler bond 126 (e.g., prior or subsequent to forming the interior perimeter bond), and forming exterior perimeter bond 124 subsequent to forming the filler bond. Forming filler bond 126 prior to forming exterior perimeter bond 124 can help to push fluid (e.g., air) present between lid 104 and body 102 out of the bond region, thereby preventing the fluid from being trapped between interior perimeter bond 122 and the exterior perimeter bond, which could result in decreased bond strength. FIG. 8 is a partial top view of some embodiments of glass package 100 manufactured by forming exterior perimeter bond 124 prior to forming filler bond 126, thereby trapping air 132 within bond 120. In contrast, forming bond 120 by forming filler bond 126 prior to forming exterior perimeter bond 124 can result in the bond being free or substantially free of trapped air as shown in FIG. 4.

The various glass components described herein can be formed from a glass material, a ceramic material, a glass-ceramic material, or a combination thereof. Additionally, or alternatively, the various glass components can be formed from the same or different materials. Package 100 comprising body 102 and lid 104 formed from glass materials can enable improved mechanical stability, operating temperature range, and/or hermeticity compared to packages formed using polymeric or other non-glass materials.

### EXAMPLES

Various embodiments will be further clarified by the following examples.

### Example 1

An example package 100 having the general configuration show in FIGS. 1-2 was formed. Package 100 had a length 134 of 60 mm, a width 136 of 60 mm, and a rim 106 thickness 138 of 0.5 mm. Cavity 108 had the shape of a square with rounded corners having a 10 mm radius. Each of base 110 of body 102 and lid 104 was formed from a glass wafer having a thickness of 0.3 mm. Rim 106 of body 102 was formed from a glass wafer having a thickness of 0.5 mm with an opening cut therein to define cavity 108. Each glass wafer was formed from a glass material commercially available from Corning Incorporated as EAGLE XG@ Glass. Each of base 110 and lid 104 was laser bonded to rim 106 using a 2-layer absorbing metallic material including a layer of Cr covered with a layer of CrON disposed on the rim between the respective layers. Each bond 120 had interior perimeter bond 122 and exterior perimeter bond 124, but omitted filler bond 126. The pitch of each of interior perimeter bond 122 and exterior perimeter bond 124 was 12 μm. Sealed cavity 108 contained air sealed therein during bonding.

Package 100 was placed in an oven at 85° C., and lid 104 cracked after 5 minutes. The cracks in lid 104 were located at the bond paths. Without wishing to be bound by any theory, it is believed that the relatively large volume of air contained in cavity 108 expanded at the higher temperature of 85° C., and the gas expansion exerted tensile stress at the bond joint trying to cleave it open. With only bonds parallel to the cavity (e.g., extending along the perimeter of the cavity and the perimeter of the package) there is a relatively large effective area over which the cleaving force can act, which may have led to failure of the glass at the bond. Package 100 was soaked in isopropyl alcohol (IPA) and water, and leakage of the fluids into cavity 108 confirmed that the cavity was no longer sealed.

### Example 2

An example package 100 was formed as described in Example 1, except that each bond 120 had inner perimeter bond 122, outer perimeter bond 124, and filler bond 126. The pitch of each of first bond paths 128 and second bond paths 130 of filler bond 126 was 200 μm. First bond paths 128 and second bond paths 130 intersected at 90° angles, thereby forming a grid pattern of squares.

Package 100 was placed in an oven at 85° C., and lid 104 did not crack after 10 minutes. Without wishing to be bound by any theory, it is believed that bond 120 supported in both parallel and perpendicular directions with respect to cavity 108 and filler bond 126 extending into the interstitial area between interior perimeter bond 122 and the cavity improve the strength of the bond.

### Example 3

An example package wafer as shown in FIG. 6 was formed. Each of base 110 of body 102 and lid 104 was formed from a glass wafer having a thickness of 0.3 mm. Rim 106 of body 102 was formed from a glass wafer having a thickness of 0.5 mm with two openings cut therein to define two adjacent cavities 108, each having the shape of a square with a length of 59 mm, a width of 59 mm, and rounded corners having a 10 mm radius. The glass wafers were bonded together as described in Example 2. A hermeticity sensor was sealed within one of the two cavities 108.

The package wafer was stored at 20° C. and 75% relative humidity for 2 days, and the humidity sensor was not activated, suggesting a hermetically sealed cavity.

The radius of curvature of lid 104 across cavity 108 without the humidity sensor was 31 m, and the radius of curvature of base 110 across the cavity without the humidity sensor was 407 m, both suggesting that the bonding process resulted in good flatness of central regions of the lid and the base.

It will be apparent to those skilled in the art that various modifications and variations can be made without departing from the spirit or scope of the claimed subject matter. Accordingly, the claimed subject matter is not to be restricted except in light of the attached claims and their equivalents.

1. A glass package comprising:
a glass body comprising a rim at least partially circumscribing a cavity within the glass body; and
a glass lid comprising a peripheral portion bonded to the rim of the glass body and a central portion overlying the cavity;
wherein a bond between the glass lid and the glass body comprises an interior perimeter bond, an exterior perimeter bond, and a filler bond;
wherein the interior perimeter bond is disposed adjacent to and extends in an interior bond path along an interior perimeter of the rim;
wherein the exterior perimeter bond is disposed adjacent to and extends in an exterior bond path along an outer perimeter of the rim; and
wherein the filler bond is disposed at least partially between the interior perimeter bond and the exterior perimeter bond and comprises a plurality of first bond paths that are substantially parallel to each other and a plurality of second bond paths that are substantially parallel to each other, and the plurality of first bond paths and the plurality of second bond paths intersect each other to form a grid pattern.

2. The glass package of claim 1, wherein the filler bond extends into an interstitial space between the interior perimeter bond and the cavity.

3. (canceled)

4. (canceled)

5. (canceled)

6. The glass package of claim 1, wherein each of the interior perimeter bond, the exterior perimeter bond, and the filler bond comprises a laser bond.

7. The glass package of claim 6, wherein the laser bond comprises a bonding material diffused into each of the glass body and the glass lid.

8. The glass package of claim 6, wherein the laser bond comprises a mixture of material of each of the glass body and the glass lid.

9. The glass package of claim 1, wherein the plurality of first bond paths and the plurality of second bond paths intersect each other at angles of 45° to 90°.

10. (canceled)

11. The glass package of claim 1, wherein each of the interior perimeter bond and the exterior perimeter bond comprises a plurality of concentric bonds or a spiral bond.

12. (canceled)

13. The glass package of claim 11, wherein a ratio of a pitch of each of the plurality of first bond paths and the plurality of second bond paths to a pitch of the interior perimeter bond or the exterior perimeter bond is 5 to 30.

14. (canceled)

15. The glass package of claim 1, wherein a ratio of a pitch of the plurality of first bond paths to a pitch of the plurality of second bond paths is 0.5 to 1.5.

16. (canceled)

17. The glass package of claim 1, wherein the central portion of the glass lid has an area of at least 2000 mm².

18. (canceled)

19. The glass package of claim 1, wherein the glass lid has a thickness of at most 0.5 mm.

20. (canceled)

21. The glass package of claim 1, wherein the rim of the glass body has a width of at most about 1 mm.

22. The glass package of claim 1, wherein each of a length and a width of the cavity is at least 50 mm.

23. The glass package of claim 1, wherein a depth of the cavity is at least 0.3 mm.

24. The glass package of claim 1, wherein a volume of the cavity is at least 1500 mm³.

25. (canceled)

26. The glass package of claim 1, wherein a thickness of the glass package is at most 1.5 mm.

27. (canceled)

28. The glass package of claim 1, wherein the cavity is hermetically sealed.

29. A method of manufacturing the glass package of claim 1 comprising:
forming the interior perimeter bond;
forming the filler bond; and
forming the exterior perimeter bond subsequent to forming the interior perimeter bond and forming the filler bond.

30. The method of claim 29, comprising forming the filler bond subsequent to forming the interior perimeter bond.

31. The method of claim 30, wherein the glass package is substantially free of gas trapped between the interior perimeter bond and the exterior perimeter bond.
